(19) United States
(12) Patent Application Publication
(10) Pub. No.: US 2009/0236632 A1
(43) Pub. Date: Sep. 24, 2009

(54) FET HAVING HIGH-K, VT MODIFYING CHANNEL AND GATE EXTENSION DEVOID OF HIGH-K AND/OR VT MODIFYING MATERIAL, AND DESIGN STRUCTURE

(76) Inventors: Brent A. Anderson, Jericho, VT (US); Andres Bryant, Burlington, VT (US); Edward J. Nowak, Essex Junction, VT (US)

Correspondence Address: HOFFMAN WARNICK LLC, 75 STATE ST, 14TH FLOOR, ALBANY, NY, 12207, US

(21) Appl. No.: 12/051,049

(22) Filed: Mar. 19, 2008

(51) Int. Cl. H01L 29/778; H01L 21/336

(52) U.S. Cl. 257/190; 438/151; 257/E21.403; 257/E29.246

(57) ABSTRACT

A field effect transistor (FET) including a high dielectric constant (high-k), threshold voltage (Vt) modifying channel and a gate extension devoid of the high-k and/or Vt modifying material, and a related design structure, are disclosed. In one embodiment, a FET may include a gate having a channel region thereunder including a gate insulator portion of a high dielectric constant (high-k) material and a threshold voltage (Vt) modifying portion (e.g., of SiGe); and a gate extension having a region thereunder devoid of at least one of the high-k material or the Vt modifying portion.

### BACKGROUND

1. Technical Field

The disclosure relates generally to integrated circuit (IC) chip fabrication, and more particularly, to a field effect transistor (FET) fabrication.

2. Background Art

Standard complementary metal-oxide semiconductor (CMOS) technology uses a polysilicon gate with a silicon oxide gate insulator with the polysilicon doped to establish a p-type field effect transistor (PFET) or n-type FET (NFET). Current CMOS technology is transitioning to metal gates that use thin, high dielectric constant (high-k) gate insulators, which further increases capacitance. One problem with using metal gates is that the gate must retain the same work function as with a polysilicon gate (i.e., band edge metal gates). In order to shift the work function, a silicon germanium (SiGe) channel is used under the gate insulator to adjust the threshold voltage (Vt). In plasma deposited semiconductor-on-insulator (PDSOI) substrates, gate contacts are made using gate extensions or extensions that do not make up part of the active gate region. The gate extension(s) add capacitance to the FET, which slows performance. The presence of the high-k material and/or SiGe under the gate extensions magnifies the capacitance issue.

### SUMMARY

A field effect transistor (FET) including a high dielectric constant (high-k), threshold voltage (Vt) modifying channel and a gate extension devoid of the high-k and/or Vt modifying material, and a related design structure, are disclosed. In one embodiment, a FET may include a gate having a channel region thereunder including a gate insulator portion of a high dielectric constant (high-k) material and a threshold voltage (Vt) modifying portion (e.g., of SiGe); and a gate extension having a region thereunder devoid of at least one of the high-k material or the Vt modifying portion.

A first aspect of the disclosure provides a field effect transistor (FET) comprising: a gate having a channel region thereunder including a gate insulator portion of a high dielectric constant (high-k) material and a threshold voltage (Vt) modifying portion; and a gate extension having a region thereunder devoid of at least one of the high-k material or the Vt modifying portion.

A second aspect of the disclosure provides a method comprising: providing a semiconductor-on-insulator (SOI) substrate including an SOI portion over a buried insulator and between isolation regions; and forming a field effect transistor over the SOI portion, the FET including: a gate having a channel region thereunder including a gate insulator portion of a high dielectric constant (high-k) material and a threshold voltage (Vt) modifying portion, and a gate extension having a region thereunder devoid of at least one of the high-k material or the Vt modifying portion.

A third aspect of the disclosure provides a design structure embodied in a machine readable medium for designing, manufacturing, or testing an integrated circuit, the design structure comprising: a field effect transistor including: a gate having a channel region thereunder including a gate insulator portion of a high dielectric constant (high-k) material and a threshold voltage (Vt) modifying portion, and a gate extension having a region thereunder devoid of the Vt modifying portion.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIGS. 1A-F depict embodiments a field effect transistor according to the disclosure.

FIGS. 2-7 depict embodiments of a method of forming the FET of FIGS. 1A-D.

FIG. 8 depicts a flow diagram of a design process used in semiconductor design, manufacture, and/or test.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

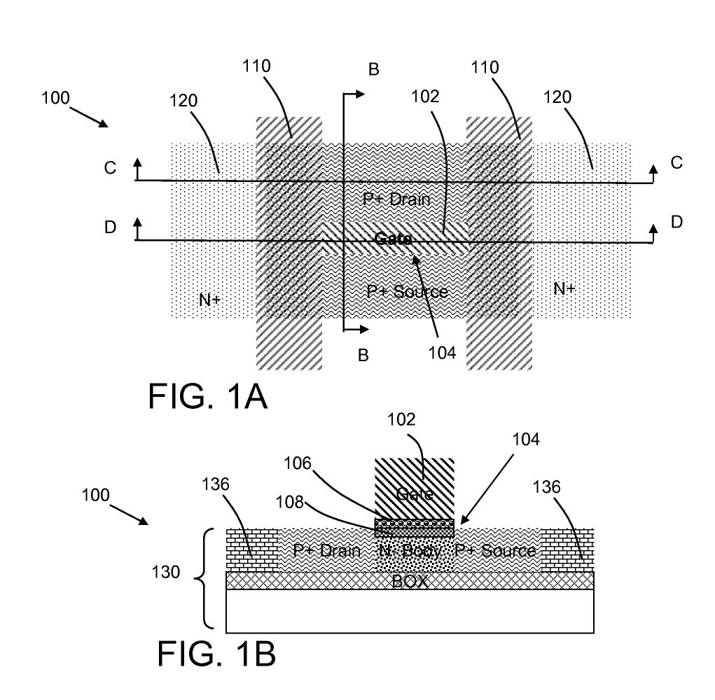

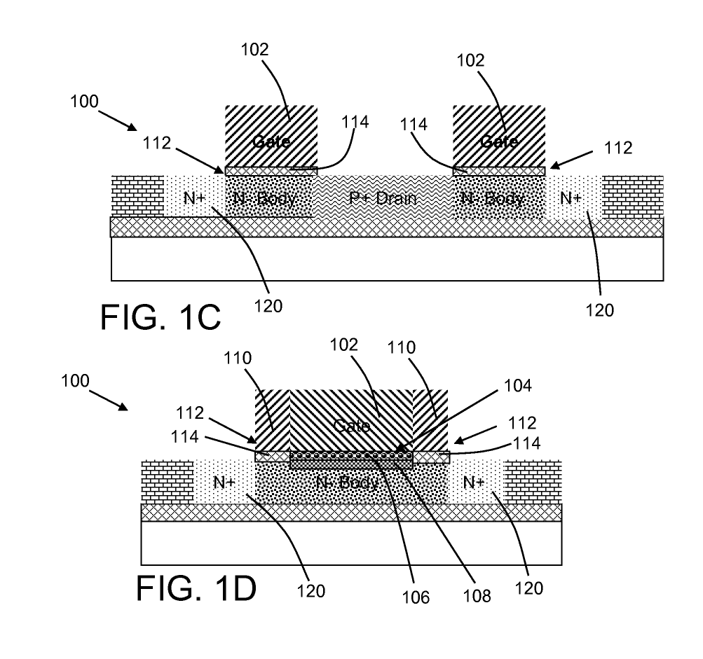

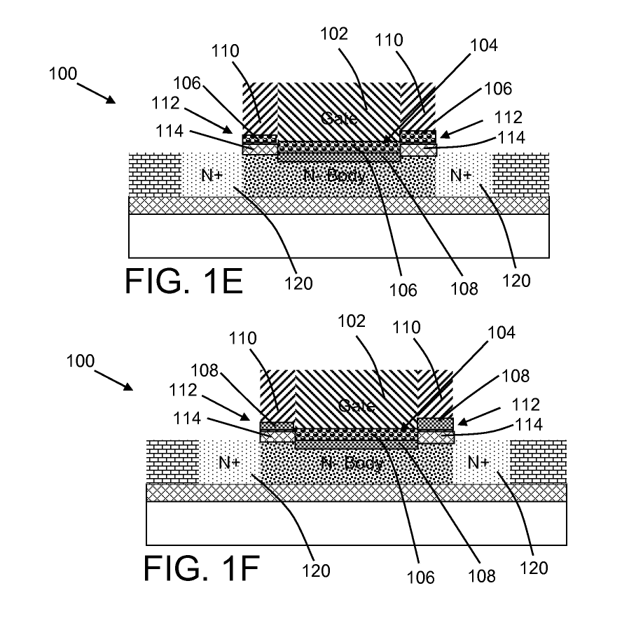

Turning to the drawings, FIGS. 1A-D show embodiments of a field effect transistor (FET) 100 according to the disclosure. FIG. 1A shows a top view of FET 100, FIG. 1B shows a cross-sectional view of FET 100 along line B-B in FIG. 1A, FIG. 1C shows a cross-sectional view of FET 100 along line C-C in FIG. 1A, and FIGS. 1D-F show a cross-sectional view of FET 100 along line D-D in FIG. 1A. As labeled in FIG. 1B only, FET 100 may be formed over a plasma deposited semiconductor-on-insulator (PDSOI) substrate 130, and be separated from other devices by trench isolations 136 (e.g., shallow trench isolations of silicon oxide (SiO₂)). In one embodiment, FET 100 includes a gate 102 having a channel region 104 thereunder including a gate insulator portion 106 of a high dielectric constant (high-k) material and a threshold voltage (Vt) modifying portion 108. Vt modifying portion 108 may include any material that modifies the flatband voltage of FET 100, thereby modifying the FET threshold voltage (Vt). In a PFET this can be done by using a silicon germanium (SiGe) layer. Silicon carbide (SiC) is another material that may be used. As understood, the SiGe layer's band gap is smaller than the underlying silicon layer's bangap, while its conduction band edge aligns with the silicon conduction band edge. As a result, the valence band is shifted in the SiGe film resulting in a PFET flatband shift and consequently a threshold voltage (Vt) reduction. That is, Vt modifying portion 108 acts to reduce a threshold voltage (Vt) of FET 100 via work function adjustment. Gate 102 may include a metal such as: aluminum (Al) or copper (Cu).

As observed best in FIGS. 1C-1F, FET 100 also includes a gate extension 110 having a region 112 thereunder devoid of high-k material of gate insulator portion 106 and/or Vt modifying portion 108. Rather, gate extension 110 includes an oxide layer 114 thereunder, e.g., silicon oxide (SiO₂). FIG. 1D shows FET 100 with neither gate insulator portion 106 nor Vt modifying portion 108 under gate extension 110; FIG. 1E shows FET 100 with gate insulator portion 106 and oxide layer 114; and FIG. 1F shows FET 100 with Vt modifying portion 108 and oxide layer 114. Oxide layer 104 may be relatively thick, e.g., it may have a thickness of greater than approximately 10 Ångstroms. As shown in FIG. 1A, gate extension 110 may take the form of an H body contact region, portions of which extend over a body contact region 120. In conventional FETs of this nature, gate extensions 110 serve no purpose relative to operation of gate 102 since they are located over body contact regions 120. As a result, they simply create parasitic capacitance. In contrast, FET 100 exhibits a highest possible threshold voltage (Vt) because of Vt modifying portion 108 and lowest capacitance due to the removal of Vt modifying portion 108 and/or high-k material (high-k portion 106) under gate extension 110. That is, by forming gate extension 110 of FET 100 over a thick oxide layer 114, a gate 102 capacitance is reduced, and by not including Vt modifying portion 108 under gate extension 110, a threshold voltage (Vt) of gate extension 110 is increased, thus reducing gate capacitance.

As illustrated, portions of FET 100 are shown with particular dopants (e.g., N, N+, P, P−, etc.) that result in a p-type FET (PFET). It is understood, however, that the teachings of the disclosure are equally applicable to an n-type FET (NFET).

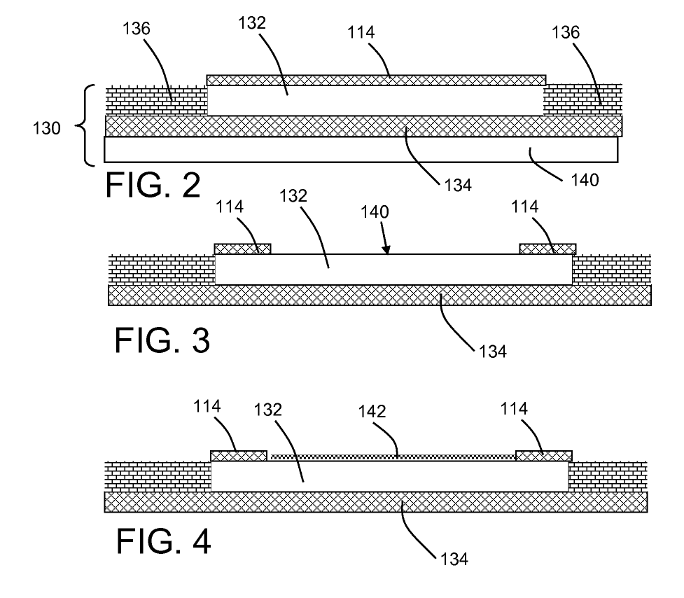

FET 100 may be formed in a number of ways. FIGS. 2-7 show embodiments of a method forming FET 100. (In FIGS. 2-7, the different shadings used in FIGS. 1A-F to denote different dopants in channel region 104 have been omitted for clarity.) FIG. 2 shows providing a semiconductor-on-insulator (SOI) substrate 130 including an SOI portion 132 over a buried insulator 134 and between isolation regions 136. The semiconductor of SOI portion 132 may include but is not limited to: silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entire semiconductor substrate may be strained. For example, SOI portion 132 may be strained. Buried insulator 134 may include any now known or later developed insulator material such as silicon oxide (SiO₂). A wafer 140 (FIG. 2 only for clarity) under SOI portion 132 may include any semiconductor material listed above.

FIGS. 3-7 show details of embodiments of forming FET 100 over SOI portion 132 including gate 102 having channel region 104 thereunder including gate insulator portion 106 of high-k material and Vt modifying portion 108 (FIGS. 1A-D), and gate extension 110 having region 112 thereunder devoid of the high-k material and/or Vt modifying portion 108. In FIGS. 2-3, oxide layer 114 is formed over SOI portion 132 adjacent to isolation regions 136, leaving a central portion 140 of SOI portion 132 exposed. In FIG. 2, oxide layer 114 is deposited, and in FIG. 3 it is patterned using any now known or later developed technique, e.g., deposit a photoresist, pattern the photoresist and etching to SOI portion 132. “Depositing” may include any now known or later developed technique appropriate for the material to be deposited including but is not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

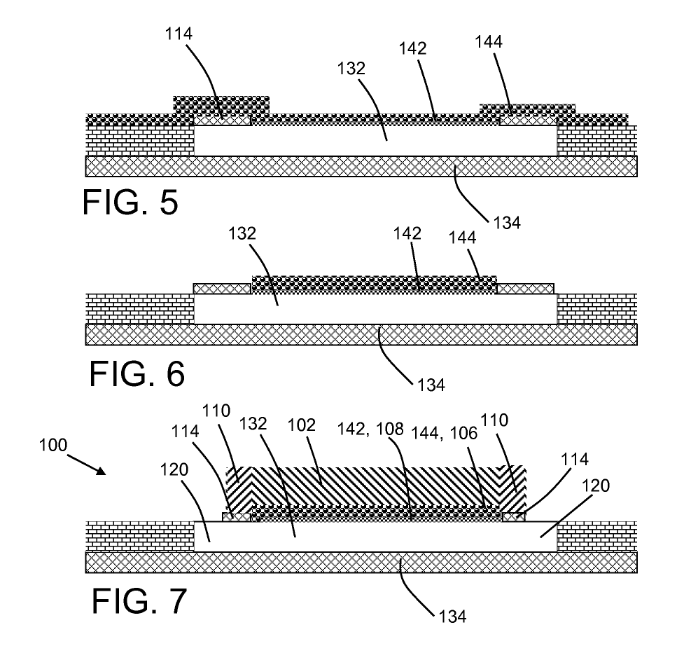

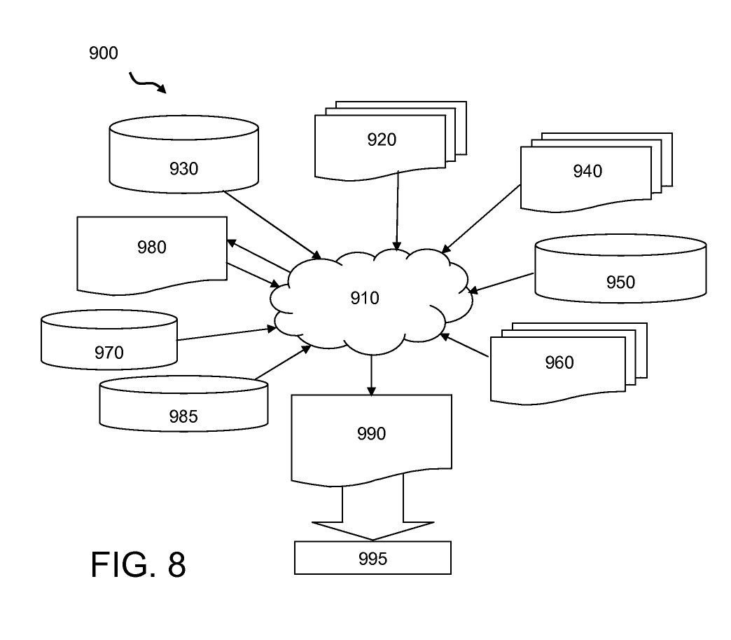

FIG. 4 shows forming Vt modifying layer 142 (eventually Vt modifying portion 108) over exposed central portion 140 (FIG. 3). Vt modifying layer 142 may include any Vt modifying material as described above such as SiGe. Vt modifying layer 142 may be deposited, or epitaxially grown. FIG. 5 shows forming a high-k layer 144 (eventually gate insulator portion 106) over Vt modifying layer 142, e.g., by deposition. High-k layer 144 may include any dielectric material having a dielectric constant (k) greater than 3.9 such as, but not limited to: Ta₂O₅, BaTiO₃, HfO₂, ZrO₂, A1₂O₃, or metal silicates such as Hf_{A1}Si_{A2}O_{A3} or Hf_{A1}Si_{A2}O_{A3}N_{A4}, where A1, A2, A3, and A4 represent relative proportions, each greater than or equal to zero and A1+A2+A3+A4 (1 being the total relative mole quantity).

FIGS. 6-7 show forming gate 102 and gate extension 110 (different shading for description purposes only—same material) over SOI portion 132. In FIG. 6, gate material such as the above-described metal(s) is deposited, and in FIG. 7, the gate material is patterned, e.g., deposit a photoresist, pattern the photoresist and etch to form gate 102 and gate extension 110. The above-described processes result in a high-k, SiGe channel region 104 under gate 102 and oxide layer 114 only under gate extension 110. Where gate insulator portion 106 or Vt modifying portion 108 are desired under gate extension 110, they may be patterned accordingly. Gate extension 110 extends over body contact region 120 (no shading provided for clarity).

FIG. 9 shows a block diagram of an exemplary design flow 900 used for example, in semiconductor design, manufacturing, and/or test. Design flow 900 may vary depending on the type of IC being designed. For example, a design flow 900 for building an application specific IC (ASIC) may differ from a design flow 900 for designing a standard component. Design structure 920 is preferably an input to a design process 910 and may come from an IP provider, a core developer, or other design company or may be generated by the operator of the design flow, or from other sources. Design structure 920 comprises an embodiment of the disclosure as shown in FIGS. 1A-D in the form of schematics or HDL, a hardware-description language (e.g., Verilog, VHDL, C, etc.). Design structure 920 may be contained on one or more machine readable medium. For example, design structure 920 may be a text file or a graphical representation of an embodiment of the disclosure as shown in FIGS. 1A-D. Design process 910 preferably synthesizes (or translates) an embodiment of the disclosure as shown in FIGS. 1A-D into a netlist 980, where netlist 980 is, for example, a list of wires, transistors, logic gates, control circuits, I/O, models, etc. that describes the connections to other elements and circuits in an integrated circuit design and recorded on at least one of machine readable medium. For example, the medium may be a CD, a compact flash, other flash memory, a packet of data to be sent via the Internet, or other networking suitable means. The synthesis may be an iterative process in which netlist 980 is re-synthesized one or more times depending on design specifications and parameters for the circuit.

Design process 910 may include using a variety of inputs; for example, inputs from library elements 930 which may house a set of commonly used elements, circuits, and devices, including models, layouts, and symbolic representations, for a given manufacturing technology (e.g., different technology nodes, 32 nm, 45 nm, 90 nm, etc.), design specifications 940, characterization data 950, verification data 960, design rules 970, and test data files 985 (which may include test patterns and other testing information). Design process 910 may further include, for example, standard circuit design processes such as timing analysis, verification, design rule checking, place and route operations, etc. One of ordinary skill in the art of integrated circuit design can appreciate the extent of possible electronic design automation tools and applications used in design process 910 without deviating from the scope and spirit of the disclosure. The design structure of the disclosure is not limited to any specific design flow.

Design process 910 preferably translates an embodiment of the disclosure as shown in FIGS. 1A-D, along with any additional integrated circuit design or data (if applicable), into a second design structure 990. Design structure 990 resides on a storage medium in a data format used for the exchange of layout data of integrated circuits and/or symbolic data format (e.g. information stored in a GDSII (GDS2), GL1, OASIS, map files, or any other suitable format for storing such design structures). Design structure 990 may comprise information such as, for example, symbolic data, map files, test data files, design content files, manufacturing data, layout parameters, wires, levels of metal, vias, shapes, data for routing through the manufacturing line, and any other data required by a semiconductor manufacturer to produce an embodiment of the disclosure as shown in FIGS. 1A-D. Design structure 990 may then proceed to a stage 995 where, for example, design structure 990: proceeds to tape-out, is released to manufacturing, is released to a mask house, is sent to another design house, is sent back to the customer, etc.

The methods and structures as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A field effect transistor (FET) comprising:
a gate having a channel region thereunder including a gate insulator portion of a high dielectric constant (high-k) material and a threshold voltage (Vt) modifying portion; and
a gate extension having a region thereunder devoid of at least one of the high-k material or the Vt modifying portion.

2. The FET of claim 1, wherein the region under the gate extension includes an oxide layer thereunder.

3. The FET of claim 2, wherein the oxide layer has a thickness in a range of greater than approximately 10 Ångstroms.

4. The FET of claim 1, wherein the FET is a p-type FET (PFET) and the Vt modifying portion includes silicon germanium (SiGe).

5. The FET of claim 1, wherein the gate includes a metal selected from the group consisting of: aluminum (Al) and copper (Cu).

6. The FET of claim 1, wherein the gate extension extends over a body contact region.

7. A method comprising:
providing a semiconductor-on-insulator (SOI) substrate including an SOI portion over a buried insulator and between isolation regions; and
forming a field effect transistor over the SOI portion, the FET including:
a gate having a channel region thereunder including a gate insulator portion of a high dielectric constant (high-k) material and a threshold voltage (Vt) modifying portion, and
a gate extension having a region thereunder devoid of at least one of the high-k material or the Vt modifying portion.

8. The method of claim 7, wherein the FET forming includes:
forming an oxide layer over the SOI portion adjacent to the isolation regions, leaving a central portion of the SOI portion exposed;
forming a silicon-germanium (SiGe) layer over the exposed central portion;
forming a high dielectric constant (high-k) layer over the SiGe layer;
forming the gate and the gate extension over the SOI portion, resulting in a high-k, SiGe channel region under the gate and the oxide layer only under the gate extension.

9. The method of claim 8, wherein the oxide layer has a thickness in a range of greater than approximately 10 Ångstroms.

10. The method of claim 8, wherein the gate and the gate extension forming includes depositing a gate material and patterning the gate material.

11. The method of claim 7, wherein the FET is a p-type FET (PFET) and the Vt modifying portion includes silicon germanium (SiGe).

12. The method of claim 7, wherein the gate includes a metal selected from the group consisting of: aluminum (Al) and copper (Cu).

13. The method of claim 7, wherein the gate extension extends over a body contact region.

14. A design structure embodied in a machine readable medium for designing, manufacturing, or testing an integrated circuit, the design structure comprising:
a field effect transistor including:
a gate having a channel region thereunder including a gate insulator portion of a high dielectric constant (high-k) material and a threshold voltage (Vt) modifying portion, and
a gate extension having a region thereunder devoid of the Vt modifying portion.

15. The design structure of claim 15, wherein the gate extension is devoid of the high-k material.

16. The design structure of claim 15, wherein the region under the gate extension includes an oxide layer thereunder.

17. The design structure of claim 15, wherein the FET is a p-type FET (PFET) and the Vt modifying portion includes silicon germanium (SiGe).

18. The design structure of claim 15, wherein the gate extension extends over a body contact region.

19. The design structure of claim 15, wherein the design structure comprises a netlist.

20. The design structure of claim 15, wherein the design structure resides on storage medium as a data format used for the exchange of layout data of integrated circuits.
